(19) United States
(12) Patent Application Publication
(10) Pub. No.: US 2014/0268991 A1
(43) Pub. Date: Sep. 18, 2014

(54) CHALCOGENIDE MATERIAL AND METHODS FOR FORMING AND OPERATING DEVICES INCORPORATING THE SAME

(71) Applicant: MICRON TECHNOLOGY, INC., Boise, ID (US)

(72) Inventors: Yongjun J. Hu, Boise, ID (US); Dale W. Collins, Boise, ID (US); Everett A. McTeer, Eagle, ID (US)

(73) Assignee: MICRON TECHNOLOGY, INC., Boise, ID (US)

(21) Appl. No.: 13/829,754

(22) Filed: Mar. 14, 2013

(51) Int. Cl. H01L 45/00; G11C 13/00

(52) U.S. Cl. CPC H01L 45/141; H01L 45/1608; G11C 13/0002
USPC 365/148; 257/2; 438/382

(57) ABSTRACT

Embodiments disclosed herein may relate to a memory cell comprising a chalcogenide material mixture having a chalcogenide composition and a metallic glass-forming composition.

### BACKGROUND OF THE INVENTION

1. Field of the Invention

Subject matter disclosed herein relates to devices in integrated circuits generally, and in particular, to devices incorporating chalcogenide materials.

2. Description of the Related Art

Devices incorporating chalcogenide materials, e.g., phase change materials, such as for example ovonic switches and memory storage elements, may be found in a wide range of electronic devices. For example, devices incorporating phase change materials may be used in computers, digital cameras, cellular telephones, personal digital assistants, etc. Factors that a system designer may consider in determining whether and how to incorporate phase change materials for a particular application may include, physical size, storage density, scalability, operating voltages and currents, read/write speed, read/write throughput, transmission rate, and/or power consumption, for example. Other example factors that may be of interest to a system designer include cost of manufacture, and/or ease of manufacture.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1 is a plan-view illustration depicting a cross-point memory array according one embodiment.

FIG. 2A is an illustration depicting a cross-sectional view of a phase change memory cell viewed along a row direction according to one embodiment.

FIG. 2B is an illustration depicting a cross-sectional view of a phase change memory cell viewed along a column direction according to one embodiment.

FIG. 3 is a graph of current versus time depicting write and read pulses applied to a phase change memory cell according to one embodiment.

FIG. 4 is a phase diagram of a chalcogenide material mixture according to one embodiment.

FIGS. 5A-5E are schematic illustrations depicting microstructural evolution as a function of temperature of a chalcogenide material.

FIGS. 6A-6E are schematic illustrations depicting microstructural evolution as a function of temperature of a chalcogenide material mixture including a metallic glass-forming composition according to an embodiment.

FIG. 7 is a graph of a resistance versus temperature for chalcogenide material mixtures with and without metallic glass-forming composition.

FIG. 8 is a time-temperature-transformation diagram of chalcogenide material mixtures with and without metallic glass-forming composition.

### DETAILED DESCRIPTION OF THE PREFERRED EMBODIMENT

Devices incorporating phase change materials, e.g. memory devices, may be found in a wide range of electronic devices. For example, devices incorporating phase change materials may be used in computers, digital cameras, cellular telephones, personal digital assistants, etc. Factors related to devices incorporating phase change materials that a system designer may consider in determining the device's suitability for a particular application may include, physical size, storage density, scalability, operating voltages and currents, read/write speed, read/write throughput, transmission rate, and/or power consumption, for example. Other example factors that may be of interest to a system designer include cost of manufacture, and/or ease of manufacture. While embodiments are described herein with respect to memory arrays, it will be understood that stabilization of phase change materials with metallic glass-forming compositions as described herein can also have application outside the memory array context.

FIG. 1A shows a cross-point memory array 10 having N×M phase change memory cells according to one embodiment of the present invention. The cross-point memory array 10 includes first through Nth columns 20-1, 20-2, . . . , and 20-N, which may be referred to as access lines, e.g., word lines. The cross-point array 10 also includes first through Mth rows 22-1, 22-2, . . . , and 22-M, which may be referred to as digit lines, e.g., bit lines. The coordinate axis marker 12 in this embodiment indicates that first through Nth columns 20-1, 20-2, . . . , and 20-N are extend along a y-direction (also referred to herein as a column direction) and first through Mth rows 22-1, 22-2, . . . , and 22-M are oriented in a x-direction (also referred to herein as a row direction). As illustrated, first through Nth columns 20-1, 20-2, . . . , and 20-N are substantially parallel to each other. Similarly, the first through Mth rows 22-1, 22-2, . . . , and 22-M are substantially parallel to each other. However, other embodiments are possible, and word lines and digit lines can have non-perpendicular orientations. As used herein, the term “substantially” intends that the modified characteristic needs not be absolute, but is close enough so as to achieve the advantages of the characteristic.

In one embodiment, first through Nth columns form a first plane that is disposed over a second plane, where the second plane is formed by first through Mth rows. In this configuration, the second plane is vertically interposed between the first plane and a semiconductor substrate whose surface forms a third plane that is substantially parallel to the first and second planes. In another embodiment, the first plane is interposed between the second plane and the semiconductor substrate.

In one embodiment, a plurality of column planes comprising first through Nth columns and a plurality of row planes comprising first through Mth rows are disposed in an alternating arrangement over a plane formed by a semiconductor substrate to form a stacked cross-point memory array.

In yet another embodiment, the first and second planes that are substantially parallel to each other but form substantially perpendicular angles with a semiconductor substrate whose surface forms a third plane.

The cross-point memory array 10 further includes a plurality of memory cells disposed at least a subset of the intersections formed by first through Nth columns and first through Mth rows. In this configuration, the cross-point memory array 10 includes up to N×M memory cells.

In one embodiment, a memory cell at an intersection of any one of first through Nth columns and any one of first through Mth rows may include a nonvolatile cross-point memory cell based on resistance change having a plurality of resistance states. Non-volatility can be measured, for example, by each of the plurality of resistance states having a resistance value that does not change by more than 50% of an as-programmed value by more than 50% over an extended time, particularly for greater than 10 seconds. More particularly, the resistance of each state may remain stable for greater than 1×10⁹ seconds.

The nonvolatile cross-point memory cell may be one of a phase change memory (PCM) cell, a resistive random access memory (RRAM) cell, a conductive bridge random access memory (CBRAM) cell, and/or a spin transfer torque random access memory (STT-RAM) cell, among other types of memory cells. In various embodiments, the memory cell may comprise a stack configuration in a cross-point array, where each cell includes a selector node coupled in series to a storage node. For example, the selector node may include a two terminal selector device, such as a diode, an ovonic threshold switch (OTS), a tunnel junction, or a mixed ionic electronic conductor (MIEC), among other two terminal selector devices. Alternatively, the selector node may include a three terminal device, such as a field effect transistor (FET) or a bipolar junction transistor (BJT), among other switching elements.

In one embodiment, any one of the memory cells disposed at an intersection formed by any one of first through Nth columns 20-1, 20-2, . . . , and 20-N and first through Mth rows 22-1, 22-2, . . . 22-M may have a resistance state that may be a relatively high resistance state, also known as the RESET state. Similarly, any one of the memory cells may have a resistance state that may be a relatively low resistance state, also known as the SET state. Under this implementation, high and low resistance states may correspond to the “1” state and a “0” state in a single bit-per-cell memory system. However, the states “1” and “0” as they relate to high and low resistance states may be used interchangeably to mean the opposite. For example, a high resistance state may be referred to as a “0” state, and a low resistance state may be referred to as a “1” state.

In other embodiments, any one of the memory cells disposed at an intersection formed by any one of the columns and rows may have a resistance state that may be an intermediate resistance state. For example, any one of the memory cells may have a resistance state that is any one of first, second, third, and fourth resistance states, wherein the first resistance state is more resistive than the second resistance state, the second resistive state is more resistive than the third resistive state, and the third restive state is more resistive than the fourth state. Under this implementation, first, second, third, and fourth resistance states may correspond to the “11,” “10,” “01”, and “00” states in a two bits-per-cell memory system. Yet other embodiments are possible, where first through eighth resistance states represent the states in a three-bits-per cell memory system, and where first through sixteenth resistance states represent the states in a four-bits-per cell memory system.

In one embodiment, each one of the memory cells disposed at an intersection formed by any one of first through Nth columns 20-1, 20-2, . . . , and 20-N and any one of first through Mth rows 22-1, 22-2, . . . , and 22-M may be accessed by an access operation. An access operation may be a write access operation, an erase access operation, or a read access operation. A write access operation, otherwise known as the program operation or a RESET operation, changes the resistance state of the memory cell from a relatively low resistance state to a relatively high resistance state. Similarly, an erase operation, otherwise known as the SET operation, changes the resistance state of the memory cell from a relatively high resistance state to a relatively low resistance state. However, the terms “write” and “erase” as they relate to RESET and SET operations may be used interchangeably to mean the opposite. For example, an erase operation may be referred to as a SET operation, and a program or write operation may be referred to as a RESET operation.

In an embodiment, each one of the memory cells disposed at an intersection formed by any of the columns and rows may be accessed individually in a bit-addressable access mode. In a bit-addressable access mode, a memory to be accessed may be a target cell 30 located at an intersection formed by an nth column 20-n and an mth row 22-m. An access voltage V_{ACCESS}, which may be a SET access voltage V_{SET}, a RESET access voltage V_{RESET}, or a read access voltage V_{READ}, may be applied across the target cell of this example by applying the access voltage across the nth column 20-n and the mth row 22-m.

In one embodiment, a target cell 30 is accessed while preventing the remaining cells from getting accessed. This is achieved by applying a voltage V_{ACCESS} across the target cell 30 while allowing for voltages substantially lower than V_{ACCESS} to be applied across the rest of the cells. In one embodiment, this is obtained by applying V_{ACCESS} to one end of the selected column (nth column 20-n in this example) while grounding one end of the selected row (mth row 22-m in this example). Concurrently, a voltage V_{COL INHIBIT} is applied across all remaining columns (first through 20-(n−1) and 20-(n+1) through 20-N columns in this example). In addition, a voltage V_{ROW INHIBIT} is applied across all remaining rows (first through 20-(m−1) and 20-(m+1) through 20-M rows in this example). Under this configuration, a voltage of about V_{ACCESS} is dropped between the nth column 20-n and the mth row 22-m across the target cell 30. In addition, a voltage of about (V_{ACCESS}−V_{ROW INHIBIT}) is dropped across inhibited cells 42 along the selected nth column 20-n and a voltage of about V_{COL INHIBIT} is dropped across inhibited cells 44 along the selected mth row 20-m. In addition, a voltage approximately equal to (V_{COL INHIBIT}−V_{ROW INHIBIT}) is dropped across all remaining deselected cells 46. In one embodiment, V_{ROW INHIBIT} and V_{COL INHIBIT} is selected to be a voltage substantially equal to V_{ACCESS}/2. In this implementation, a voltage substantially equal to V_{ACCESS}/2 is dropped across inhibited cells 42 along the selected nth column and across inhibited cells 44 along the selected mth row and a voltage substantially equal to zero is dropped across deselected cells 46. A person skilled in the art will recognize that the actual voltages that similarly situated cells receive may deviate from the voltage applied at one of the ends of a column or a row due to various parasitic resistances and capacitances to which a particular cell may be subject to under a particular access condition.

Any one of the intersections formed by first through Nth columns and first through Mth rows in a cross-point memory array 10 may include a memory cell. FIG. 2A illustrates one example embodiment of a memory cell 60 viewed in a direction parallel to the first through Mth rows (x direction). FIG. 2B illustrates the memory cell 60 of FIG. 2A viewed in a direction parallel to the first through Nth columns (y direction). In the embodiment of FIG. 2A, the memory cell 60 is interposed between two adjacent memory cells 62 disposed on neighboring rows. FIG. 2B illustrates the memory cell 60 is interposed between two adjacent memory cells 64 disposed under neighboring columns. The coordinate axis marker 14 indicates that in FIG. 2A, first through Nth columns extend in a y-direction across the page and first through Mth rows extend in the x-direction in and out of the page. The coordinate axis marker 16 indicates that in FIG. 2B, first through Nth columns extend in a y-direction in and out of the page and first through Mth rows are oriented in the x-direction across the page. In addition, the coordinate axis markers 14 and 16 indicate a z-direction that is perpendicular to both the x and the y directions. While in this embodiment, x, y, and z directions are depicted as being perpendicular to each other, other embodiments are possible wherein any one of x, y, and z directions deviate substantially from being perpendicular to any other direction.

The memory cell 60 in FIGS. 2A and 2B is in a stack configuration including a second electrode 40 on any one of first through Mth rows extending in the x direction, a storage node 38 on the second electrode 40, a middle electrode 36 on the storage node 38, a selector node 34 on the middle electrode 36, a first electrode 32 on the selector node 34, and any one of first through Nth columns on the first electrode extending in the y direction. Other embodiments of a stack configuration are possible. For example, the positions of the storage node 38 and the selector node 34 within a stack configuration may be interchanged with one another. In other examples, any one of the first, second, and middle electrodes may be interchanged with one another.

In the embodiment of FIG. 2A, any one of column electrodes 20, a first electrode 32, a selector node 34, a middle electrode 36, a storage node 38, a second electrode 40, and any one of row electrodes 22 have first through seventh lateral dimensions in the x-direction d₁ₐ, d₂ₐ, d₃ₐ, d₄ₐ, d₅ₐ, d₆ₐ, and d₇ₐ, respectively. In addition, an eighth dimension d₈ₐ in the y-direction represents a spacing between a memory cell 60 and an adjacent memory cell 62 on a neighboring row. In FIG. 2A, the first lateral dimension in the y-direction d₁ₐ represents a column length of column electrodes 20 of the cross-point memory array 10. In one embodiment, the second through seventh lateral dimensions in the y-direction d₂ₐ, d₃ₐ, d₄ₐ, d₅ₐ, d₆ₐ, and d₇ₐ result from patterning and etching within a single photo mask level a first stack 52 comprising the first electrode 32, the selector node 34, the middle electrode 36, the storage node 38, the second electrode 40, and row electrodes 22. Under certain implementations, second through seventh lateral dimensions in the y-direction are substantially similar in value to one another, especially when relative etch biases of the individual layers within the first stack 52 are relatively low. Under other implementations, second through seventh lateral dimensions in the y-direction can be substantially different in value to one another, especially when relative etch biases of the individual layers within the first stack 52 are relatively high, or when individual layers are etched in separate steps.

Similarly, in the embodiment of FIG. 2B, any one of column electrodes 20, the first electrode 32, the selector node 34, the middle electrode 36, the storage node 38, the second electrode 40, and row electrodes 22 have first through seventh lateral dimensions in the x-direction d_{1b}, d_{2b}, d_{3b}, d_{4b}, d_{5b}, d_{6b}, and d_{7b}, respectively. In addition, an eighth dimension d_{8b} in the x-direction represents the spacing between the memory cell 60 and an adjacent memory cell 64 under a neighboring column, as measured between two adjacent columns within column electrodes 20. In FIG. 2B, the seventh lateral dimension in the x-direction d_{7b} represents a row length of any one of row electrodes 22 in the cross-point memory array 10. In addition, the first through sixth lateral dimensions in the x-direction d_{1b}, d_{2b}, d_{3b}, d_{4b}, d_{5b}, and d_{6b} result from patterning and etching within a single photo mask level a second stack 54 comprising one of column electrodes 20, the first electrode 32, the selector node 34, the middle electrode 36, the storage node 38, and the second electrode 40. Under certain implementations, first through sixth lateral dimensions in the x-direction are be substantially close in value to one another, especially when relative etch biases of the individual layers within the second stack 54 are relatively low. Under other circumstances, first through sixth lateral dimensions in the x-direction are substantially different in value to one another, especially when relative etch biases of the individual layers within the second stack 54 are relatively high, or when individual layers are etched in separate steps.

The first lateral dimension in the y-direction d₁ₐ representing a column length of any one of column electrodes 20 in the cross-point memory array 10 is a function of the number of rows M the column electrode 20 traverses in the y-direction. For example, in an array with M rows where d₈ₐ represents the spacing between a memory cell 60 and an adjacent memory cell 62 in on a neighboring row, d₁ₐ may be at least (M×d₇ₐ)+(M×d₈ₐ). Similarly, the seventh lateral dimension in the x-direction d_{7b} representing a row length of any one of the row electrodes 22 in the cross-point memory array 10 is a function of the number of columns N the row electrode 22 traverses in the x-direction. For example, in an array with N columns where d_{8b} represents the spacing between the memory cell 60 and an adjacent memory cell 64 under a neighboring column, the d_{7b} may be at least (N×d_{1b})+(N×d_{8b}).

In one embodiment, d₂ₐ, d₃ₐ, d₄ₐ, d₅ₐ, d₆ₐ, and d₇ₐ in FIG. 2A resulting from patterning and etching the first stack 52 within a single photo mask level, have dimensions selected to be the range between about 40 nm and 60 nm, for example 50 nm. In another embodiment, d₂ₐ, d₃ₐ, d₄ₐ, d₅ₐ, d₆ₐ, and d₇ₐ have dimensions selected to be the range between about 25 nm and 40 nm, for example 35 nm. In another embodiment, d₂ₐ, d₃ₐ, d₄ₐ, d₅ₐ, d₆ₐ, and d₇ₐ have dimensions selected to be the range between about 18 nm and 25 nm, for example 20 nm. In yet another embodiment, d₂ₐ, d₃ₐ, d₄ₐ, d₅ₐ, d₆ₐ, and d₇ₐ have dimensions selected to be the range between about 5 nm and 18 nm, for example 14 nm. Smaller dimensions are yet possible, limited only by the lithographic capability employed by the person skilled in the art.

Similarly, d_{1b}, d_{2b}, d_{3b}, d_{4b}, d_{5b}, and d_{6b} in FIG. 2B resulting from patterning and etching the second stack 54 within a single photo mask level, have dimensions selected to be the range between about 40 nm and 60 nm, for example 50 nm. In another embodiment, d_{1b}, d_{2b}, d_{3b}, d_{4b}, d_{5b}, and d_{6b} have dimensions selected to be the range between about 25 nm and 40 nm, for example 35 nm. In another embodiment, d_{1b}, d_{2b}, d_{3b}, d_{4b}, d_{5b}, and d_{6b} have dimensions selected to be the range between about 18 nm and 25 nm, for example 20 nm. In yet another embodiment, d_{1b}, d_{2b}, d_{3b}, d_{4b}, d_{5b}, and d_{6b} have dimensions selected to be the range between about 5 nm and 18 nm, for example 14 nm. Smaller dimensions are yet possible, limited only by the lithographic capability employed by the person skilled in the art.

The memory cell 60 in FIGS. 2A and 2B includes one of the column electrodes 20 having a first thickness h₁, the first electrode 32 having a second thickness h₂, the selector node 34 having a third thickness h₃, the middle electrode 36 having a fourth thickness h₄, the storage node 38 having a fifth thickness h₅, the second electrode 40 having a sixth thickness h₆, and one of the row electrodes 22 having a seventh thickness h₇. In one embodiment, the first thickness h₁ has a thickness selected to be the range between about 10 nm and 100 nm, for example 35 nm, the second thickness h₂ has a thickness selected to be the range between about 10 nm and 50 nm, for example 25 nm, the third thickness h₃ has a thickness selected to be the range between about 5 nm and 50 nm, for example 25 nm, the fourth thickness h₄ has a thickness selected to be the range between about 10 nm and 100 nm, for example 25 nm, the fifth thickness h₅ has a thickness selected to be the range between about 10 nm and 50 nm, for example 25 nm, the sixth thickness h₆ has a thickness selected to be the range between about 10 nm and 100 nm, for example 25 nm, and the seventh thickness h₇ has a thickness selected to be the range between about 10 nm and 100 nm, for example 50 nm.

The column electrodes 20 and row electrodes 22 may comprise any suitable conductive and semi conductive material including n-doped poly silicon, p-doped poly silicon, metals including Al, Cu, and W, conductive metal nitrides including TiN, TaN, and TaCN. The first, middle, and second electrodes 32, 36, and 40 may comprise any suitable conductive and semiconductive materials including n-doped poly silicon and p-doped poly silicon, metals including C, Al, Cu, Ni, Cr, Co, Ru, Rh, Pd, Ag, Pt, Au, Ir, Ta, and W, conductive metal nitrides including TiN, TaN, WN, and TaCN, conductive metal silicides including tantalum silicides, tungsten silicides, nickel silicides, cobalt silicides, and titanium silicides, and conductive metal oxides including RuO₂.

In one embodiment, the memory cell 60 may include the selector node 34 electrically coupled to the first electrode 32 and to the middle electrode 36 to form a two terminal selector device. When the selector node 34 comprises a chalcogenide composition, the two terminal selector device may be referred to as an Ovonic Threshold Switch (OTS). In another embodiment, the memory cell 60 may include the storage node 38 electrically coupled to the middle electrode 36 and the second electrode 40 to form a two terminal storage device. When the storage node 38 comprises a chalcogenide composition, the two terminal storage device may be referred to as a Phase Change Memory (PCM). In yet another embodiment, the memory cell 60 may include a selector node electrically coupled to a first electrode 32 and a middle electrode 36 to form a two terminal selector device and further include a memory node 38 electrically coupled to the middle electrode 36 and a second electrode 40 to form a two terminal storage device coupled to the two terminal selector device electrically in series.

With reference to the memory cell 60 of FIGS. 2A-2B, a person skilled in the art will understand that while either or both the selector node 34 and the storage node 38 may include chalcogenide compositions, the electrical behaviors of the selector node 34 and the storage node 38 may differ substantially. In particular, both the selector node 34 and the storage node 38 including chalcogenide compositions are known to exhibit threshold switching. Threshold switching refers to a switching event from a high resistivity state to a low resistivity state of the storage node 38 or the selector node 34 when an electric field across the chalcogenide composition included therein exceeds a certain threshold field Eₜₕ. In one model, the threshold switching phenomenon is described as an electronic phenomenon, whose process is initiated in part by charged defect traps in conduction band of the chalcogenide composition being filled by energetic carriers. While the selector node 34 and the storage node 38 including chalcogenide compositions exhibit threshold switching under an electric field, a distinction is made based on the microstructure change after the electric field has been turned off. In particular, when the electric field across the storage node 38 including a chalcogenide composition is raised above Eₜₕ, the microstructure of the chalcogenide composition transforms from a microstructure having an amorphous region to a predominantly crystalline microstructure substantially free of the amorphous region, as detectable using conventional characterization techniques such as transmission electron microscopy and X-ray diffraction. The transformation is due at least in part to the raised temperature of the storage node 38 as a result of conducting a current Iₜₕ at Eₜₕ. In contrast, when the electric field across the selector node 34 including a chalcogenide composition is raised above Eₜₕ, any transformation in microstructure comparable to that in the storage node 38 is not detectable using conventional characterization techniques such as transmission electron microscopy and X-ray diffraction. In a selector node 34, the chalcogenide composition retains a predominantly amorphous microstructure before and after the application of Eₜₕ.

In one embodiment, a storage node may include a chalcogenide composition such as an alloy including at least two of the elements within the indium (In)-antimony (Sb)-tellurium (Te) (IST) alloy system, e.g., In₂Sb₂Te₅, In₁Sb₂Te₄, In₁Sb₄Te₇, etc., an alloy including at least two of the elements within the germanium (Ge)-antimony (Sb)-tellurium (Te) (GST) alloy system, e.g., Ge₈Sb₅Te₈, Ge₂Sb₂Te₅, Ge₁Sb₂Te₄, Ge₁Sb₄Te₇, Ge₄Sb₄Te₇, etc., among other chalcogenide alloy systems. The hyphenated chemical composition notation, as used herein, indicates the elements included in a particular mixture or compound, and is intended to represent all stoichiometries involving the indicated elements. Other chalcogenide alloy systems include Ge—Te, In—Se, Sb—Te, Ga—Sb, In—Sb, As—Te, In—Ge—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt, for example.

In one embodiment, a selector node may include a chalcogenide composition including any one of the chalcogenide alloy systems described above for a for a storage node. In addition, a selector node may further comprise an element to suppress crystallization, such as arsenic (As). When added to an alloy system comprising one of the chalcogenide alloy systems described above, an element such as As suppresses crystallization by inhibiting any non-transitory nucleation and/or growth of the alloy, as detectable using conventional ex-situ characterization techniques such as transmission electron microscopy and X-ray diffraction. Examples include Te—As—Ge—Si, Ge—Te—Pb, Ge—Se—Te, Al—As—Te, Se—As—Ge—Si, Se—As—Ge—C, Se—Te—Ge—Si, Ge—Sb—Te—Se, Ge—Bi—Te—Se, Ge—As—Sb—Se, Ge—As—Bi—Te, and Ge—As—Bi—Se, among others.

In other embodiments, the selector node can include a chalcogenide composition, while the storage node may include other examples of variable resistance materials such as binary metal oxide, complex metal oxides, spin-torque magnetic material, and/or various polymer based resistive variable materials, among others. Examples of oxide-based resistance variable materials may include metal oxide materials, e.g., NiO, HfO₂, ZrO₂, Cu₂O, TaO₂, Ta₂O₅, TiO₂, SiO₂, Al₂O₃, VO₂, and/or alloys including two or more metals, e.g., transition metals, alkaline earth metals, and/or rare earth metals such as PrCaMnO, SrRuO, and SrTiO.

FIG. 3 schematically illustrates exemplary access operations including RESET, SET, and READ operations performed on a memory cell according to one embodiment. The memory cell that exhibits the behavior of FIG. 3 includes a storage node including a chalcogenide material mixture electrically coupled to and disposed between a middle electrode and a second electrode to form a two terminal Phase Change Memory (PCM), similar to the memory cell 60 of FIGS. 2A and 2B. The memory cell can further include a selector node which also includes a chalcogenide material mixture electrically coupled to and disposed between a top electrode and a middle electrode. The access operations are represented as a current and temperature versus time curve 80. The primary y axis on the left represents a current magnitude measured in, for example, Amps (A), the secondary y axis represents a temperature magnitude measured in, for example, Celsius (° C.), and the x axis represents time measure in, for example, seconds (sec).

In this embodiment, a RESET operation is performed by applying a RESET current pulse 82 to a storage node in a low resistance SET state comprising a substantially crystalline chalcogenide material. The RESET current pulse 82 may have a rising portion associated with a characteristic RC delay of the cross-point memory array, e.g., a 1/e delay, followed by a main pulse portion having a RESET pulse width t_{RESET}. A melting condition 82a is reached when the current flowing through the storage node reaches a melting current Iₘ. At the melting condition 82a, at least a portion of the storage node has reached a melting temperature T_{M} of the chalcogenide alloy of the storage node. A peak RESET condition 82b is reached when the current flowing through the storage node reaches a peak RESET current I_{RESET}. At the peak RESET condition 82b, at least a portion of the storage node has reached a peak RESET temperature T_{RESET} higher than T_{M} of the chalcogenide material mixture of the storage node. Upon reaching the peak RESET condition 82b, the storage node is rapidly quenched within a time duration t_{QUENCH} that is short enough to prevent substantial crystallization of the chalcogenide material. In some embodiments, t_{QUENCH} may be substantially limited by and equal to a characteristic RC delay time, e.g., a 1/e delay time, associated with the cross-point memory array. Upon completion of the RESET operation at the end of t_{QUENCH}, the storage node is in a high resistance RESET state, including a substantially amorphous portion of the chalcogenide material mixture. A READ operation may be performed by applying a READ voltage pulse having a voltage V_{READ} and a pulse width t_{READ} to the storage node in a RESET state and sensing the resulting I_{READ} current pulse 84 of the RESET state. The RESET state can be represented by the RESET state read condition 84a characterized by a I_{READ} of the RESET state.

According to one embodiment, a RESET current pulse width t_{RESET} measured between a RC rising edge and a RC falling edge is chosen to be in a range between 1 and 100 nanoseconds. According to another embodiment, the RESET current pulse width t_{RESET} is chosen to be between 1 and 50 nanoseconds. According to yet another embodiment, the RESET current pulse width t_{RESET} is chosen to be between 5 and 20 nanoseconds.

According to one embodiment, t_{QUENCH} associated with the 1/e RC falling edge is chosen to be in a range between 10⁻¹¹ and 10⁻⁸-seconds, for example about one nanosecond.

FIG. 3 further illustrates an embodiment where a SET operation is performed by applying a SET current pulse 86 to a storage node in a high resistance RESET state comprising a substantially amorphous portion of the chalcogenide material. In some embodiments, the SET current pulse 86 has a rising portion of the pulse associated with a characteristic RC delay characteristic of the cross-point memory array, followed by a main pulse portion having a SET pulse width t_{SET}. In other embodiments, the rising portion of the SET pulse may be chosen to be longer than the characteristic RC delay of the cross-point array, which may provide for a more efficient SET operation, such as lower energy consumed during the SET operation. A crystallization condition 86a is reached when the current flowing through the storage node reaches a crystallization current I_{c}. At the crystallization condition 86a, at least a portion of the memory node has reached a crystallization temperature T_{c} of the chalcogenide material mixture of the storage node. A peak SET condition 86b is reached when the current flowing through the storage node reaches a peak SET current I_{SET}. At the peak SET condition 86b, at least a portion of the memory node has reached a peak SET temperature T_{SET} higher than T_{c} of the chalcogenide material mixture of the storage node. In some embodiments, SET current pulse 86 has a falling portion associated with a characteristic RC delay of the cross-point memory array. In other embodiments, the falling portion of the SET pulse may be chosen to be longer than the characteristic RC delay of the cross-point array, which may provide for a more efficient SET operation, such as lower energy consumed during the SET operation. A READ operation may be performed by applying a read voltage pulse having a read voltage V_{READ} and a pulse width t_{READ} to the storage node in a SET state and sensing the resulting I_{READ} current pulse 88 of the RESET state. The SET state is represented by the SET state read condition 88a characterized by a I_{READ} of the SET state.

According to one embodiment, a SET current pulse width t_{SET} measured between a RC rising edge and a RC falling edge is chosen to be in a range between 50 and 1000 nanoseconds. According to another embodiment, the RESET current pulse width t_{SET} is chosen to be in a range between 50 and 500 nanoseconds. According to yet another embodiment, the RESET pulse width t_{SET} is chosen to be in a range between 100 and 300 nanoseconds.

FIG. 4 illustrates a schematic phase diagram 90 of a chalcogenide composition of a storage node according to one embodiment of the present invention. The illustration is by way of an example only, and it does not represent an actual phase diagram of a known chalcogenide material. However, similar features may be found in many chalcogenide material systems. For example, the features found in FIG. 4 illustrate several regions of phase diagrams of more commonly used chalcogenide material systems such as Ge—Sb—Te, In—Sb—Te, and In—Ge—Te, among others. As discussed below, letters A, B, and C denote a terminal composition. A terminal composition may be an element or a compound. For example, A and B in a Sb—Te binary system denote Sb and Te, respectively and in a Ge—Te binary system denote Ge and Te, respectively. An example of terminal compositions A and B in a Ge—Sb—Te ternary system includes GeTe and Sb₂Te₃, respectively, among other terminal compositions. Other examples include GeₓTe_{y} and Sb_{w}Te_{z}, GeₓTe_{y} and In_{w}Te_{z}, In_{w}Te_{z} and SbₓTe_{y}, etc., wherein x, y, w, and z are integers. Also as discussed below, Greek symbols (α, β, γ) refer to a thermodynamically stable solid phase at the given composition and temperature. The liquid phase is denoted by the letter L. While a certain phase region may be explained below as being bounded thermodynamically and physically by several other phase regions, a person skilled in the art will understand that the embodiments described herein are equally applicable where the certain phase region is thermodynamically and physically bounded by a subset of the other phase regions or bounded by additional phase regions not described herein.

A person skilled in the art will understand that while the phase diagram in FIG. 4 is discussed primarily reference to a storage node, it does not preclude application to a chalcogenide composition of selector node. As discussed above, a chalcogenide composition of a selector node does not undergo a substantial and permanent phase change upon application of an electric field exceeding Eₜₕ, as detectable using conventional ex-situ characterization techniques such as transmission electron microscopy and X-ray diffraction A person skilled in the art will understand that a lack of phase change does not necessarily signify a lack of thermodynamically stable phases. Instead, a lack of phase change may signify a lack of kinetically unachievable phases within the conditions (e.g., time and temperature) specified. As a result, the phase diagram in FIG. 4 may be applicable in the context of transient formation of certain phases, as an example. This is discussed more in connection with FIGS. 5 and 6.

In the embodiment of FIG. 4, the y axis represents the temperature of the chalcogenide composition, for example, in ° C. and the x axis represents the concentration X of a chalcogenide alloy having a first terminal composition A where X=0% and a second terminal composition B (X=100%). The phase diagram 90 includes an α phase region 92 bounded by the first terminal composition A, an α+L phase region 98, an and α+β phase region 94. The α+β phase region 94 is bounded by the α phase region 92, the α+L region 98, a L phase region 104, a γ phase region 100, and a β phase region 96. The β phase region 96 is bounded by the second terminal composition B, the α+β phase region 94, and the γ phase region 100. The α+L phase region 98 is bounded by the first terminal composition A, the α phase region 92, the L phase region 104, the γ phase region 100, and the α+β phase region 94. The L phase region 104 is bounded by the first terminal composition A, the α+L phase region 98, a γ+L phase region 102, the γ phase region 100, and the second terminal composition B. The γ phase region 100 is bounded by the α+L phase region 98, the L phase region 104, the α+β phase region 94, the β phase region 96, the γ+L phase region 102, and the second terminal composition B. The γ+L phase region 102 is bounded by the L phase region 104, the γ phase region 100, and the second terminal composition B.

In one embodiment, the memory cell 60 of FIGS. 2A and 2B includes a chalcogenide material mixture disposed between the first and second electrodes 32 and 40. The chalcogenide material mixture comprises a chalcogenide composition such as C₀ in the phase diagram 90 of FIG. 4. The chalcogenide composition C₀ corresponds to an equilibrium phase diagram composition having a first solid equilibrium phase corresponding to a first solid equilibrium temperature range and a second solid equilibrium phase corresponding to a second solid equilibrium temperature range lower than the first solid equilibrium temperature range. In the illustrative embodiment of FIG. 4, the first solid equilibrium phase corresponds to a γ phase within the γ phase region 100 and a first solid equilibrium temperature range corresponds to the temperature range T_{C}≦T≦T_{M}, where the crystallization temperature T_{C} corresponds to a crystallization condition 86a of the γ phase and melting temperature T_{M} corresponds to the melting condition 82a of the γ phase. Also in the illustrative embodiment of FIG. 4, the second solid equilibrium phase may correspond to α and β phases within the α+β phase region 94 and the second solid equilibrium temperature range corresponds to the temperature range T_{RT}≦T≦T_{C}, where the room temperature T_{RT} corresponds to a room temperature condition (e.g., 23° C.) and the crystallization temperature (T_{C}) corresponds to the crystallization condition 86a of the γ phase.

A person skilled in the art will recognize that the phase regions α region 92, β region 96, α+β region 94, γ region 100, α+L region 98, and γ+L region 102 in the phase diagram 90 represent idealized equilibrium phase regions. When a chalcogenide material mixture such as that comprising a chalcogenide composition C₀ is disposed between first and second electrodes 32 and 40 of a memory cell 60 as illustrated in FIGS. 2A and 2B and is subjected to a current pulse, such as the SET current pulse 86 in FIG. 3, many deviations from idealized equilibrium phases may arise.

In one embodiment, a deviation from idealized equilibrium phases arises as a result of the chalcogenide material mixture being placed under a physical condition such as the crystallization condition 86a and a peak SET condition 86b for a finite duration of time. As a result of limiting the pulse by the finite duration of time, in many embodiments, the material mixture may not have sufficient time to phase transform into the respective phases represented in the phase diagram 90.

In another embodiment, a deviation from idealized equilibrium phases arises as a result of the chalcogenide material mixture being located at different locations within the cross-point memory array 10. For example, where each one of the intersections formed by column electrodes 20 and row electrodes 22 of the cross-point memory array 10 of FIG. 1 includes a memory cell, such as a memory cell 60 in FIG. 2, each memory cell may be subject to a unique condition when subjected to a SET current pulse 86 in FIG. 3. The unique condition may arise from various factors, such as different electrical and thermal environment to which each memory cell is subject. For example, different electrical conditions for different memory cells within the cross-point memory array 10 may result from being located at different positions along the length d₁ₐ of a column electrode 20, which gives rise to varying degrees of IR voltage drop and parasitic capacitances. Similarly, different electrical conditions for different memory cells within the cross-point memory array 10 may result from being located at different positions along the length d_{7b} of a row electrode 22, which gives rise to varying degrees of IR voltage drop and parasitic capacitances.

In yet other embodiments, a deviation from idealized equilibrium phases can arise as a result of various processing variables. For example, non-uniform film composition across the memory array footprint, non-uniform deposition temperature across the memory array footprint, and non-uniform film thickness across the memory array footprint, and/or non-uniform patterning and etching across the memory array footprint can give rise to deviations of varying degrees.

While the phase diagram 90 indicates that under idealized equilibrium conditions the chalcogenide composition C₀ of a chalcogenide material mixture disposed between electrodes and subject to a SET current pulse, e.g., a SET current pulse 86 of FIG. 3, should crystallizes into a first solid equilibrium phase, such as a pure γ phase, the chalcogenide composition subject to deviations from the idealized equilibrium conditions described above may comprise other phases. For example, the chalcogenide material may include an additional second solid equilibrium phase such as α and β phases of the α+β phase region 94, which is a lower temperature phase of the C₀ chalcogenide composition compared to the γ phase. In other examples, the chalcogenide material mixture C₀ may include third and fourth solid equilibrium phases such as α phase of the α region 92 and/or β phase of the β region 96.

A person skilled in the art will recognize that despite having similar atomic fractions of individual atomic elements between different phases, such as the first solid equilibrium phase represented by γ phase of the γ region 100 in FIG. 4 and a second solid equilibrium phase represented by α and β phases of the α+β region 100, the physical properties of the first and second solid equilibrium phases having the same chalcogenide composition C₀ may differ substantially. In one example, a chalcogenide composition C₀ having α and β phases of the α+β region 94 has a first electrical conductivity and a chalcogenide composition C₀ having a γ phase of the γ phase region 100 has a second electrical conductivity different from the first electrical conductivity. In another example, a chalcogenide composition C₀ having α and β phases of the α+β region 94 has a first thermal conductivity and a chalcogenide composition C₀ having a γ phase of the γ phase region 100 has a second thermal conductivity different from the first thermal conductivity.

In another example, the first and second solid equilibrium phases of a chalcogenide composition C₀ γ phase of the γ region 100 and α and β phases of the α+β region 100 have different crystallization temperatures. As illustrated in FIG. 4, a chalcogenide composition C₀ has a first crystallization temperature within a first solid equilibrium temperature range T_{C}≦T≦T_{M} in the γ region 100 in FIG. 4 corresponding to a first solid equilibrium phase represented by γ phase of the γ region 100. In addition, the chalcogenide composition C₀ has a second crystallization temperature within a second solid equilibrium temperature range T_{RT}≦T≦T_{C} in the α+β region 94 in FIG. 4 corresponding to a second solid equilibrium phase represented by α+β phase of the α+β region 94.

In some implementations where a chalcogenide material mixture having a chalcogenide composition C₀ disposed between electrodes of a memory cell is subject to a SET current pulse, it is desirable to have a single phase resulting from the SET current pulse, such as the γ phase of the γ region 100. This is because different phases having different physical properties as described above result in different memory cells within a cross-point memory array having different device parameters including I_{SET}, I_{RESET}, and I_{READ}. Different cells within a cross-point memory array having different device parameters results in the memory having wide distributions of I_{SET}, I_{RESET}, and I_{READ}, which in turn results in higher requirements of V_{SET}, V_{RESET}, and V_{READ}. To mitigate these potentially adverse effects resulting from the chalcogenide material mixture having multiple solid equilibrium phases, various impurities may be added to the chalcogenide material mixture.

In one embodiment, a metallic glass-forming composition is added to the chalcogenide material mixture as an impurity to mitigate the effects resulting from having multiple solid equilibrium phases of a chalcogenide composition such as C₀ in FIG. 4 as described above. A metallic glass-forming composition is an alloy composition that includes a first metal element A and a second metal element B, wherein each of the first and second metal elements A and B can be crystalline metals in element forms. Under ordinary circumstances, the individual elements A and B and mixtures thereof are very difficult to quench into an amorphous state due their fast crystallization rate. Under certain circumstances, however, an alloy including the first metal element A and the second metal element B forms a glass-forming composition that can be quenched into an amorphous or pseudo-amorphous solid phase from a liquid phase.

In one embodiment, the metallic glass-forming composition includes between about 1% and 30% of the chalcogenide material mixture. In another embodiment, the metallic glass-forming composition includes between about 1% and 20% of the chalcogenide material mixture. In yet another embodiment, the metallic glass-forming composition includes between about 1% and 10% of the chalcogenide material mixture.

In one embodiment, an alloy composition including a first metal element A and a second metal element B forms a metallic glass-forming composition AₓB_{y} wherein the first metal element A is an early transition metal element chosen from Group IIIB, Group IVB, and Group VB of the periodic table of elements including, for example, Sc, Y, a lanthanide element, an actinide element, Ti, Zr, Hf, V, Nb, and Ta. In addition, the second metal element B is an element chosen from Group VIII, Group IB, and Group IIB of the periodic table of elements, including, for example, Cu, Ag, Au, Fe, Co, Ni, Pd, Pt, Co, Rh, Ir, Fe, Ru, Os, Zn, Cd, and Hg. In one implementation, exemplary glass-forming compositions include: ZrₓCu₁₋ₓ where X_{Zr}=0.05 to 0.10, for instance 0.068, X_{Zr}=0.4 to 0.5, for instance 0.486, and X_{Zr}=0.7 to 0.8, for instance 0.730; ZrₓNi₁₋ₓ where X_{Zr}=0.01 to 0.2, for instance 0.100, X_{Zr}=0.3 to 0.4, for instance 0.367, X_{Zr}=0.4 to 0.5, for instance 0.426, X_{Zr}=0.5 to 0.6, for instance 0.592, and X_{Zr}=0.7 to 0.8, for instance 0.713; HfₓCu_{1-X} where X_{Hf}=0.01 to 0.1, for instance 0.066 and X_{Hf}=0.3 to 0.4, for instance 0.341; NbₓNi₁₋ₓ where X_{Nb}=0.1 to 0.2, for instance 0.103 and X_{Nb}=0.4 to 0.6, for instance 0.410; and NiₓTi₁₋ₓ where X_{Ni}=0.2 to 0.3, for instance 0.230, X_{Ni}=0.6 to 0.7, for instance 0.619, and X_{Ni}=0.8 to 0.9, for instance 0.854.

In another embodiment, an alloy composition including a first metal element A and a second metal element B form a metallic glass-forming composition AₓB_{y} wherein the first metal element A is an early transition metal element chosen from Group IIIB, Group IVB, and Group VB of the periodic table of elements, and the second metal element B is an element chosen from Group VIII, Group IB, and Group IIB of the periodic table of elements, wherein the first metal element A has a first atomic radius and the second metal element B has a second atomic radius, wherein the difference between the first and second atomic radii is at least 12.5% relative to the larger of the first and second atomic radii. In another embodiment, the difference between the first and second atomic radii is at least 20% relative to the larger of the first and second atomic radii.

In yet another embodiment, an alloy composition including a first metal element A, a second metal element B, and a third metal element C form a metallic glass-forming composition AₓB_{y}C_{z}. In this embodiment, the first metal element A is an early transition metal element chosen from Group IIIB, Group IVB, and Group VB of the periodic table of elements including, for example, Sc, Y, a lanthanide element, an actinide element, Ti, Zr, Hf, V, Nb, and Ta. The second metal element B is an element chosen from Group VIII, Group IB, and Group IIB of the periodic table of elements including, for example, Cu, Ag, Au, Fe, Co, Ni, Pd, Pt, Co, Rh, Ir, Fe, Ru, Os, Zn, Cd, and Hg. The third metal element an element chosen between one of Al, and an element chosen from Group IIIB, Group IVB, and Group VB of the periodic table of elements, or an element chosen from Group VIII, Group IB, and Group IIB. The third metal element may be selected, for example, from a group consisting of Al, Cu, Ag, Au, Fe, Co, Ni, Pd, Pt, Rh, Ir, Fe, Ru, Os, Zn, Cd, and Hg, Sc, Y, a lanthanide element, an actinide element, Ti, Zr, Hf, V, Nb, and Ta. In one embodiment, the atomic percentage of the third metal element is about 1-10%.

The first, second, and third metal elements have first, second, and third atomic radii, and the third metallic glass-forming element has a third atomic radius wherein the difference between the first and third atomic radii is at least 12.5% and the difference between the second and third atomic radii is at least 12.5%. In this example, the difference between the first and second atomic radii can be as much as 25%. In another embodiment, the difference between the first and third atomic radii is at least 20% and the difference between the first and second atomic radii is at least 20%. In this example, the difference between the first and second atomic radii can be as much as 40%. In one implementation, exemplary glass-forming compositions include Zr₅₀₋ₓCu₅₀Tiₓ where 0≦X≦10 and (Zr_{0.5}Cu_{0.5})₁₀₀₋ₓAlₓ where 5≦X≦10. In another implementation, exemplary glass-forming compositions include Cu_{X}Zr_{Y}Ag_{Z}, In yet another implementation, exemplary glass glass-forming compositions include Zr_{62-X}Ti_{X}Al₁₀Cu₂₀Ni₈. In these exemplary compositions, X, Y, and Z are integers.

The memory device 60 of FIGS. 2A and 2B can comprise a chalcogenide material mixture disposed between the first electrode 32 and the second electrode 40, wherein the chalcogenide material mixture comprises a chalcogenide composition such as the chalcogenide composition C₀ of FIG. 4 intermixed with one of the metallic glass-forming compositions described above. FIGS. 5A-5E and 6A-6E illustrate the effect of having a metallic glass-forming composition intermixed with a chalcogenide composition on the mixture's microstructure in undergoing a phase transformation in response to a SET current pulse. In these examples, the chalcogenide material mixture is employed as the storage node of the memory device 60 in FIG. 2. The microstructural evolution of a chalcogenide composition without a metallic glass-forming composition is first illustrated in FIGS. 5A-5E, followed by the microstructural evolution of a chalcogenide material mixture including both the chalcogenide composition and a metallic glass-forming composition in FIGS. 6A-6E. While the embodiment in FIGS. 6A-6E is illustrated primarily as it applies to a chalcogenide composition of a storage node, principles described herein may be extended to application in selector nodes, as described below in connection with FIG. 6E.

FIG. 5A illustrates the chalcogenide material mixture having a chalcogenide composition C₀ of a storage node after a RESET operation has been performed. For example, the RESET operation may be performed using a RESET current pulse 82 prior to being given a SET pulse 86 as illustrated in FIG. 3. Prior to the initiation of a SET pulse 86, the chalcogenide material mixture is at room temperature (T=T_{RT}) and includes a first amorphous region 110a comprising a predominantly amorphous mixture of a chalcogenide composition, such as a chalcogenide composition C₀ in FIG. 4. The first amorphous region 110a at room temperature (T_{RT}) is substantially free of crystalline phases.

FIG. 5B illustrates the chalcogenide material mixture in the storage node 38 at a rising portion of the SET pulse 86 of FIG. 3. In the rising portion of the SET pulse 86, the chalcogenide material mixture is at a temperature between T_{RT} and a crystallization temperature T_{C} of γ phase. In this example, the temperature of the material mixture is T=T_{LOW} as illustrated in FIG. 4. At T_{LOW}, the material mixture includes a first amorphous region 110b at T_{LOW}, α phase nuclei 112a of the α+β region 94 at T_{LOW}, and β phase nuclei 114a of the α+β region 94 at T_{LOW}. The first amorphous region 110b at T_{LOW} may be substantially free of other crystalline phases. α phase nuclei 112a of α+β region 94 have an average diameter d₁₀ₐ and β phase nuclei 114a of α+β region 94 have an average diameter d₁₂ₐ.

FIG. 5C illustrates the chalcogenide material mixture in the storage node 38 at or near the beginning of the main portion of the SET pulse 86 of FIG. 3. At or near the beginning of the main portion of the SET pulse 86, the chalcogenide material mixture may be at a temperature at or near the crystallization temperature T_{C} of γ phase. At T_{C}, the material mixture includes α phase grains 112b of α+β region 94 at T_{C}, β phase grains 114b of α+β region 94 at T_{C}, and first γ phase nuclei 116b of γ region 100 at T_{C}. The α, β, and γ phase grains 112b, 114b, and 116b may be separated from each other by grain boundaries 118b. α phase grains 112b of α+β region 94 at T_{C} have an average diameter d_{10b} greater than the average diameter d₁₀ₐ of α phase nuclei 112a of α+β region 94 at T_{LOW} (FIG. 5B). β phase grains 114b of α+β region 94 at T_{C} have an average diameter d_{12b} greater than the average diameter d₁₂ₐ of β phase nuclei 114a of α+β region 94 at T_{LOW} (FIG. 5B). First γ phase nuclei 116b of γ region 100 have an average diameter d_{14b}.

FIG. 5D illustrates the chalcogenide material mixture in the storage node 38 at a main portion of the SET pulse 86 of FIG. 3. At the main portion of the SET pulse 86, the chalcogenide material mixture may be at a temperature exceeding the crystallization temperature T_{C} of γ phase. In this example, the chalcogenide material mixture is at T=T_{PRESET} as illustrated in FIG. 4. At T_{PRESET}, the material mixture includes α phase grains 112c of α+β region 94, β phase grains 114c of α+β region 94, and first γ phase grains 116c of γ region 100. The α, β, and γ phase grains 112c, 114c, and 116c may be separated from each other by grain boundaries 118c. The chalcogenide mixture at this temperature may be substantially free of amorphous regions. α phase grains 112c of α+β region 94 have an average diameter d₁₀ greater than the average diameter d_{10b} of α phase grains 112b of α+β region 94 at T_{C} (FIG. 5C). β phase grains 114c of α+β region 94 have an average diameter d_{12c} greater than the average diameter d_{12b} of β phase grains 114b of α+β region 94 at T_{C} (FIG. 5C). First γ phase grains 116c of γ region 100 at T_{PRESET} have an average diameter d_{14c} greater than the average diameter d_{14b} of first γ phase grains 116b of region 100 at T_{C} (FIG. 5C).

FIG. 5E illustrates the chalcogenide material mixture in the storage node 38 at a peak SET condition 86b of the SET pulse 86 of FIG. 3. At the peak SET condition 86b of the SET pulse 86, the chalcogenide material mixture may be at a temperature of T_{SET} exceeding the crystallization temperature T_{C} and T_{PRESET} of γ phase as illustrated in FIG. 4. At T_{SET}, the material mixture includes first γ phase grains 116d of γ region 100 at T_{SET}. The γ phase grains 116d may be separated from each other by grain boundaries 118b. The chalcogenide mixture may be substantially free of α phase grains 112c of α+β region 94, β phase grains 114c of α+β region 94, and amorphous regions. First γ phase grains 116d of γ region 100 have an average diameter d_{14d} greater than the average diameter d_{14c} of first γ phase grains 116c of region 100 at T_{PRESET} (FIG. 5D).

The microstructural evolution of a chalcogenide material mixture according to one embodiment including a chalcogenide composition and further including a metallic glass-forming composition is now illustrated. FIG. 6A illustrates the chalcogenide material mixture of a storage node 38 after a RESET operation has been performed with a RESET current pulse 82, prior to being given a SET pulse 86 in FIG. 3. Prior to the initiation of a SET pulse 86, the chalcogenide material mixture is at room temperature (T=T_{RT}) and may include a second amorphous region 120a at room temperature T_{RT}, which is predominantly amorphous and substantially free of crystalline phases. The second amorphous region 120a is similar to the first amorphous region 110a of FIG. 5A, comprising an amorphous mixture of a chalcogenide composition such as C₀ in FIG. 4, except that the amorphous region 120a additionally includes a metallic glass-forming composition such as AₓB_{y} or AₓB_{y}C_{z} described above.

FIG. 6B illustrates the chalcogenide material mixture in the storage node 38 at a rising portion of the SET pulse 86 of FIG. 3. In the rising portion of the SET pulse 86, the chalcogenide material mixture may be at a temperature between T_{RT} and a crystallization temperature T_{C} of γ phase at a chalcogenide composition C₀ according to the equilibrium phase diagram. In this example, the chalcogenide material mixture is at T=T_{Low} as illustrated in FIG. 4. At T_{LOW}, the chalcogenide material mixture includes a second amorphous region 120b at T_{Low} that is predominantly amorphous and remains substantially free of crystalline phases. Unlike the chalcogenide material mixture of FIG. 5B, the chalcogenide material mixture including a metallic glass-forming composition may be substantially free of α phase nuclei 112a of the α+β region 94, and may be substantially free of β phase nuclei 112b of the α+β region 94.

FIG. 6C illustrates the chalcogenide material mixture in the storage node 38 at or near a beginning of the main portion of the SET pulse 86 of FIG. 3. At that stage, the chalcogenide material mixture may be at a temperature at or near the crystallization temperature T_{C} of γ phase at a chalcogenide composition C₀ according to the equilibrium phase diagram. At T_{C}, the material mixture includes a third amorphous region 124b and further includes second γ phase nuclei 122b of γ region 100 according to the equilibrium phase diagram. Each of the second γ phase nucleus 122b may be substantially free of the metallic glass-forming composition. Due to precipitation of second γ phase nuclei 122b, the third amorphous region 124b at T_{C} is richer in metallic glass-forming composition compared to the second amorphous region 120b of FIG. 6B. Unlike the chalcogenide material mixture of FIG. 5C, the chalcogenide material mixture including a metallic glass-forming composition may be substantially free of α phase grains 112b of α+β region 94 and substantially free of β phase grains 114b of α+β region 94 while γ phase nuclei begin to form. Second γ phase nuclei 122b of γ region 100 have an average diameter d_{18b}.

FIG. 6D illustrates the chalcogenide material mixture in the storage node 38 at a main portion of the SET pulse 86 of FIG. 3. At the main portion of the SET pulse 86, the chalcogenide material mixture is at a temperature exceeding the crystallization temperature T_{C} of γ phase at a chalcogenide composition C₀ according to the equilibrium phase diagram. In this example, the chalcogenide material mixture is at T=T_{PRESET} as illustrated in FIG. 4. At T_{PRESET}, the chalcogenide material mixture includes a third amorphous region 124c and further includes second γ phase grains 122c of γ region 100 according to the equilibrium phase diagram. Each of the second γ phase grain 122c may be substantially free of the metallic glass-forming composition. Due to growth of second γ phase grains 122c, the third amorphous region 124c at T_{PRESET} is more concentrated with the metallic glass-forming composition compared to the third amorphous region 124b of FIG. 6C at T_{C}. Unlike the chalcogenide material mixture of FIG. 5D, the chalcogenide mixture having a metallic glass-forming composition may continue to be substantially free of α phase grains 112b of α+β region 94 and substantially free of β phase grains 114b of α+β region 94 at T_{C} while the γ phase nuclei continue to grow. Second γ phase grains 122c of γ region 100 have an average diameter d_{18c} greater than the average diameter d_{18b} of second γ phase grains 122b of region γ phase region 100 at T_{C} (FIG. 6C). On the other hand, second γ phase grains 122c of γ region 100 have an average diameter d_{18c} smaller than the average diameter d_{14c} of first γ phase grains 116c of γ phase region 100 of FIG. 5D at T_{PRESET}.

FIG. 6E illustrates the chalcogenide material mixture in the storage node 38 at a peak SET condition 86b of the SET pulse 86 of FIG. 3. At the peak SET condition 86b of the SET pulse 86 of FIG. 3, the chalcogenide material mixture may be at a temperature T_{SET} exceeding the crystallization temperature T_{C} and T_{PRESET} of γ phase at a chalcogenide composition C₀ according to the equilibrium phase diagram as illustrated in FIG. 4. At T_{SET}, the chalcogenide material mixture includes a third amorphous region 124d at T_{SET} and further includes second γ phase grains 122d of γ region 100 according to the equilibrium phase diagram. Each of the second γ phase nuclei 122d may be substantially free of the metallic glass-forming composition. Due to further growth of second γ phase grains 122d at T_{SET} compared to second γ phase grains 122c of FIG. 6D at T_{PRESET}, the third amorphous region 124d at T_{SET} is further concentrated with the metallic glass-forming composition compared to the third amorphous region 124c of FIG. 6D at T_{PRESET} and may be substantially free of the chalcogenide composition. Like the chalcogenide material mixture of FIG. 5E, the chalcogenide mixture having a metallic glass-forming composition may be substantially free of α phase nuclei and β phase nuclei. Second γ phase grains 122d of γ region 100 have an average diameter d_{18d} greater than the average diameter d₁₈ₑ of second γ phase grains 122c of region 100 at T_{PRESET}. On the other hand, second γ phase grains 122d of γ region 100 have an average diameter d_{18d} smaller than the average diameter d_{14d} of first γ phase grains 116d of region 100 of FIG. 5E at T_{SET}.

As discussed herein, parameters relating to the degree of crystallinity, including an average size of grains, can be determined using any suitable techniques known to a person skilled in the art. For example, a full-width at half-maximum of an X-ray diffraction peak can be used to determine an average grain size of a crystalline phase. Conversely, an absence of an X-ray diffraction peak may indicate an absence of a crystalline phase. Similarly, a full-width at half-maximum of an electron diffraction ring under a transmission electron microscope can be used to determine an average grain size of a crystalline phase. Conversely, absence of an electron diffraction ring may indicate an absence of a crystalline phase. In one embodiment, as determined by a suitable technique, the chalcogenide material mixture comprising a chalcogenide composition and a metallic glass-forming composition in a storage node 40 of FIG. 6E at a peak SET condition includes second γ phase grains 122d having an average diameter d_{18d} between 1 and 50 nm. In another embodiment, the average diameter d_{18d} of the second γ phase grains 122d at a peak SET condition is between 1 and 30 nm. In yet another embodiment, the average diameter d_{18d} of the second γ phase grains 122d at a peak SET condition is between 3 and 15 nm.

The foregoing describes how a mixture of a chalcogenide with a metallic glass-forming composition can be useful as a chalcogenide material mixture for a storage node, having stable amorphous and crystalline states with different electrical resistivity values. A person skilled in the art will appreciate that degrees of crystallinity, and the associated degrees of electrical resistivity may be described as a continuously varying parameter. For example, for a given chalcogenide material mixture, the state with the lowest electrical resistivity may be obtained when the entire chalcogenide material mixture is a single crystal of a given phase having no grain boundaries. On the other hand, the state with the highest electrical resistivity may be obtained when the entire chalcogenide material mixture is an amorphous mixture with no nuclei or grains. In practice, the state of the chalcogenide material mixture is generally somewhere between being fully single crystalline and fully amorphous. In general, the electrical resistivity may be generally inversely proportional to the grain size of the chalcogenide material mixture. Thus, in the example of FIG. 6E, provided that the γ phase is the predominant electrically conductive phase in the chalcogenide mixture, the microstructure of FIG. 6E having substantially smaller grains compared to the microstructure of 5E, is expected to result in a higher electrical resistivity of the storage node containing the chalcogenide mixture.

In addition, as discussed above in connection with the distinction between a storage node and a selector node including chalcogenide mixtures, a person skilled in the art will also appreciate that certain chalcogenide compositions are intrinsically more difficult to crystallize compared to other chalcogenide compositions. One reason for this may be that the kinetics of phase transformation is intrinsically slower in these compositions. For example, as described above in connection with compositions suitable for a selector node, chalcogenide compositions including Te—As—Ge—Si, Ge—Te—Pb, Ge—Se—Te, and Al—As—Te require higher temperatures and longer times to achieve the same degree of crystallinity and/or average grain size compared to other chalcogenide compositions. As a result, these particular compositions have been used as chalcogenide compositions for selector nodes. However, some of these compositions contain toxins such as Arsenic and are not manufacturing-friendly. Thus, there is a need for chalcogenide compositions without toxic elements, or with a lower concentration of toxic elements, to be included in the selector node of the memory cell.

In one embodiment, a metallic glass-forming composition is intermixed with non-toxic chalcogenide compositions to provide a chalcogenide material mixture for the selector node that does not undergo a stable phase transformation upon application of electric field exceeding Eₜₕ, as detectable using conventional ex-situ characterization techniques such as transmission electron microscopy and X-ray diffraction. In this embodiment, the electrical resistivity of the selector node is lowered temporarily during while an access voltage V_{ACCESS} is applied across the selector node, which results in the electric field in the chalcogenide composition exceeding Eₜₕ. The electrical resistivity automatically returns to a higher value upon lowering the voltage V_{ACCESS}, resulting in the electric field in the chalcogenide composition falling below Eₜₕ. In one embodiment, the non-toxic chalcogenide compositions are chalcogenide compositions that do not include As, which is a well-known toxin. The microstructural evolution and the associated embodiments are discussed below.

As illustrated in FIGS. 6A-6E and the counterpart FIGS. 5A-5E, at a given temperature, a chalcogenide material mixture including a chalcogenide composition C₀ and a metallic glass-forming composition has grain sizes smaller than a chalcogenide material mixture including a chalcogenide composition C₀ but without a metallic glass-forming composition. In some embodiments, for example, average grain diameter d_{18d} of γ phase grains in FIG. 6E at T_{SET} is substantially smaller than average grain diameter d_{14d} of γ phase grains in FIG. 5E. The effect of suppressing grain growth by the addition of metallic glass-forming compositions into chalcogenide material mixtures can be more extensive in other embodiments. For example, in some embodiments, d_{18d} (FIG. 6E) may be substantially smaller than d_{14c} at T_{PRESET} (FIG. 5D), or d_{14b} at T_{C} (FIG. 5C). Still in other embodiments, the addition of metallic glass-forming compositions into chalcogenide material mixtures can suppress formation of stable nuclei altogether. As a person skilled in the art will appreciate, a stable grain forms when the size of a nucleus exceeds a certain critical size. For example, for a spherical nucleus, the critical size may be expressed by the following equation, where r* is the critical radius, σ is the interfacial energy between the parent amorphous phase and the crystalline nucleus, and ΔGᵥ is the volume free energy of formation of the crystalline phase:

$${r}^{*} = - \frac{2 σ}{Δ {G}_{v }} \qquad ( 1 )$$

Thus, the addition of metallic glass-forming compositions can suppress formation of stable nuclei by increasing σ or decreasing ΔGᵥ, for example, such that the chalcogenide material mixture may not form crystalline phases within the temperature regimes of interest. Thus, a selector node that does not form crystalline phases may be formed by addition of metallic glass-forming compositions to a chalcogenide material mixture.

In one exemplary embodiment incorporating this concept, the memory device 60 of FIG. 2 comprises a first electrode 32, a second electrode 40, and a chalcogenide material mixture disposed in a selector node between the first and second electrodes 32 and 40 wherein the chalcogenide material mixture comprises a chalcogenide composition such as the chalcogenide composition C₀ of FIG. 4 intermixed with one of the metallic glass-forming composition described above. In this embodiment, upon receiving an I_{SET} sufficient to raise a peak temperature of the selector node to a temperature as high as T_{SET}, the chalcogenide material mixture of the selector node remains substantially amorphous.

In one embodiment described above in connection with FIGS. 6A-6E, the chalcogenide material mixture comprises the metallic glass-forming composition comprising about 1 and 10 atomic percentage of the chalcogenide material mixture. In another embodiment described above in connection with FIGS. 6A-6E, the chalcogenide material mixtures comprises the metallic glass-forming composition comprising about 10 and 15 atomic percentage of the chalcogenide material mixture. In yet another embodiment described above in connection with FIGS. 6A-6E, the chalcogenide material mixture comprises the metallic glass-forming composition comprising about 15 and 20 atomic percentage of the chalcogenide material mixture.

As an illustration, kinetics of amorphous-to-crystalline phase transformation of the embodiments of a chalcogenide material mixture disposed between the first and second electrodes 32 and 40 is described using a resistance versus temperature (R-T) diagram 130 in FIG. 7. An R-T diagram may be obtained by measuring, for example, a sheet resistance of a thin film of a chalcogenide material mixture using a method such as a four-point probe method and plotting the resistance value in the y-axis while the thin film is being heated at a constant temperature ramp rate (measured for instance in ° C./sec) plotted in the x-axis.

Referring to FIG. 7, the kinetics of amorphous-to-crystalline phase transformation of one embodiment of a memory device such as the memory device 60 of FIG. 2 comprising a first electrode 32, a second electrode 40, and a chalcogenide material mixture comprising a chalcogenide composition is illustrated by a first R-T curve 132. The chalcogenide composition of the chalcogenide material mixture can be a composition such as the chalcogenide composition C₀ of FIG. 4. The first R-T curve 132 includes, in the direction of increasing temperature, a first plateau region 132a, followed by a first transformation point 132b, followed by a first transformation region 132c, followed by a second plateau region 132d, followed by a second transformation point 132e, followed by a second transformation region 132f. Prior to obtaining a first R-T curve 132, the chalcogenide material mixture is fully amorphized by applying a RESET pulse such as the RESET current pulse 82 in FIG. 3. In the first plateau region 132a, the resistance of the chalcogenide composition is relatively unchanging and may correspond to, for example, the temperature range between T_{RT} and T_{LOW} in FIG. 4. In the first plateau region 132a, the chalcogenide material mixture may have microstructures similar to those described with respect to FIGS. 5A and 5B and may include, for example, first amorphous regions 110a or 110b and may further include α phase nuclei and β phase nuclei of α+β region 112a. The first transformation point 132b may correspond to, for example T_{LOW} in FIG. 4. The chalcogenide composition at the first transformation point 132b may have a microstructure similar to that described in FIG. 5B and may include, for example, α and β phase nuclei of α+β region 94. The first transformation region 132c is characterized by a relatively rapid decline in resistance and may correspond to, for example, the temperature range between T_{LOW} and a mid-point between T_{LOW} and T_{C} in FIG. 4. The chalcogenide composition at the first transformation region 132c may have microstructures similar to those described in FIG. 5B and may include, for example, α and β phase nuclei or grains of α+β region 94. The second plateau region 132d is characterized by a relatively rapid unchanging resistance and may correspond to, for example, the temperature range between the mid-point between T_{LOW} and T_{C} and T_{C} in FIG. 4. The chalcogenide composition at the second plateau region 132d may have microstructures similar to those described in FIG. 5B and may include, for example, α and β phase grains of α+β region 94 that are substantially larger than α and β phase nuclei or grains of α+β region 94 at the first transformation. In addition, at temperature approximately at T_{C}, first γ phase nuclei of γ region 100 may start to appear. The second transformation point 132e may correspond to, for example T_{C} in FIG. 4. The chalcogenide composition at the second transformation point 132e may have a microstructure similar to that described in FIG. 5C or 5D and may include, for example, α and β phase grains of α+β region 94, first γ phase nuclei of γ region 100. The second transformation region 132f is characterized by a relatively rapid decline in resistance and may correspond to, for example, the temperature range between T_{C} and T_{SET} in FIG. 4. The chalcogenide composition at the second transformation region 132f may have microstructures similar to those described in FIGS. 5C, 5D, and 5E and may include, for example, α and β phase grains of α+β region 94, and first γ phase grains of γ region 100.

In one embodiment, a first change in resistance ΔR₁ occurring within the first transformation region 132c is between 1× and 1,000×. In another embodiment, ΔR₁ is between 1× and 100×. In yet another embodiment, ΔR₁ is between 1× and 10×.

In one embodiment, a second change in resistance ΔR₂ occurring within the second transformation region 132e is between 1× and 1,000×. In another embodiment, ΔR₂ is between 1× and 100×. In yet another embodiment, ΔR₂ is between 1× and 10×.

Referring still to FIG. 7, the kinetics of amorphous-to-crystalline phase transformation of one embodiment of a memory device such as the memory device 60 of FIG. 2 comprising a first electrode 32, a second electrode 40, and a chalcogenide material mixture comprising a chalcogenide composition and a metallic glass-forming composition is illustrated by a second R-T curve 134. The chalcogenide composition of the chalcogenide material mixture can be a composition such as the chalcogenide composition C₀ of FIG. 4, while the metallic glass-forming composition includes AₓB_{y} or AₓB_{y}C_{z} compositions described above. The second R-T curve 134 includes, in the direction of increasing temperature, a third plateau region 134a, followed by a third transformation point 134b, followed by a third transformation region 134c. Prior to obtaining a second R-T curve 134, the chalcogenide material mixture is fully amorphized by applying a RESET pulse such as the RESET current pulse 82 in FIG. 3. In the third plateau region 134a, the resistance of the chalcogenide material mixture is relatively unchanging and may correspond to, for example, the temperature range between T_{RT} in FIG. 4 to a T_{C}′ higher than T_{C} in FIG. 4. In the third plateau region 134a, the chalcogenide material mixture may have microstructures similar to those described in FIG. 6A, 6B, or 6C, and may include, for example, second amorphous regions 120a, 120b, or 124b and may further include γ phase nuclei 122b. The third transformation point 134b may correspond to, for example T_{C}′ higher than T_{C} in FIG. 4. The chalcogenide material mixture at the third transformation point 134b may have a microstructure similar to that described in FIG. 6C and may include, for example, a second amorphous region 124b and may further include γ phase nuclei 122b. The third transformation region 134c is characterized by a relatively rapid decline in resistance and may correspond to, for example, the temperature range between T_{C}′ higher than T_{C} and T_{SET}′ higher than T_{SET} in FIG. 4. The chalcogenide composition at the third transformation region 134c may have microstructures similar to those described in FIGS. 6C, 6D, and 6E and may include, for example, third amorphous regions 124b, 124c, or 124d, and first γ phase grains 122b, 122c, and 122d.

In one embodiment, a third change in resistance ΔR₃ occurring within the third transformation region 134c is between 1× and 10,000×. In another embodiment, ΔR₃ is between 10× and 10,000×. In yet another embodiment, ΔR₃ is between 10× and 1,000×.

In one embodiment, T_{C}′ of a chalcogenide material mixture including both a chalcogenide composition and a metallic glass-forming composition is higher than T_{C} of a chalcogenide material mixture including the same chalcogenide composition without the metallic glass-forming composition by a temperature difference in the range of 1° C. to 100° C. In another embodiment, T_{C}′ is higher than T_{C} by a temperature difference in the range of 1° C. to 50° C. In yet another embodiment, T_{C}′ is higher than T_{C} by a temperature difference in the range of 1° C. to 20° C.

In one embodiment, T_{SET}′ of a chalcogenide material mixture including both a chalcogenide composition and a metallic glass-forming composition is higher than T_{SET} of a chalcogenide material mixture including the same chalcogenide composition without the metallic glass-forming composition by a temperature difference in the range of 1° C. to 100° C. In another embodiment, T_{SET}′ is higher than T_{SET} by a temperature difference in the range of 1° C. to 50° C. In yet another embodiment, T_{SET}′ is higher than T_{SET} by a temperature difference in the range of 1° C. 20° C.

As a further illustration, kinetics of amorphous-to-crystalline phase transformation of the embodiments of a chalcogenide material mixture is described using a time-temperature-transformation (TTT) diagram 150 in FIG. 8. A TTT diagram 150 has a y-axis representing the temperature of the chalcogenide material mixture and an x-axis representing log of time it takes for a material system to complete a phase transformation. The time it takes complete a phase transformation can be measured at, for example 1% of volume transformation, 50% of volume transformation, or 99% of volume transformation. A TTT diagram is characterized by a “nose,” which represents the temperature at which the phase transformation is the fastest. A TTT diagram also illustrates time to complete the transformation at higher and lower temperatures, for example the time to complete transformation at room temperature T_{RT} which may correspond to data retention time of the storage node of a memory device. The time difference between the time to transform at the nose and the time to transform at room temperature can be a critical factor for a person skilled in the art in designing the memory device 60 of FIG. 2. Where fast SET speed t_{SET} and long retention time t_{RET} is desired, a ratio of t_{RET}/t_{SET} that is as large as possible is desired. As a general rule, the time for phase transformation t_{cryst} at a given temperature T is governed by an Arrhenius relationship:

$${t}_{Cryst} ∝ exp [ \frac{- {E}_{a}}{{k}_{B} T} ] \qquad ( 2 )$$

Referring to FIG. 8, the kinetics of amorphous-to-crystalline phase transformation of one embodiment of a memory device comprising a chalcogenide material mixture comprising a chalcogenide composition but without a metallic glass-forming composition is illustrated by a first TTT curve 154. The chalcogenide composition of the chalcogenide material mixture can be a composition such as the chalcogenide composition C₀ of FIG. 4. The first TTT curve 154 includes a first nose 154a and a first retention point 154b. At the origin of the TTT diagram 150, the chalcogenide material mixture is fully amorphized by applying a RESET pulse such as the RESET current pulse 82 in FIG. 3. The first nose 154a represents a condition for fastest temperature-time combination, and is represented by a temperature for maximum transformation rate (fastest speed) T_{SET,FS} and a corresponding time-to-transform t_{SET,FS}. In one embodiment, where the storage node of a memory device is optimized to SET at or near a maximum speed, t_{SET,FS} and T_{SET,FS} may substantially correspond to t_{SET} and T_{SET} of FIG. 3. In other embodiments, where the storage node of a memory device is optimized to SET at a speed less than a maximum speed, t_{SET,FS} may correspond to a SET time shorter than t_{SET} of FIG. 3 and T_{SET,FS} may correspond to a SET temperature deviating from T_{SET} of FIG. 3. The first retention point 154b represents the time it takes for a fully amorphized chalcogenide material mixture to complete crystallization at room temperature T_{RT}. A person skilled in the art will recognize that the concept of retention time practically applies to the storage node of a memory device but not to the selector node because the chalcogenide material of a selector node does not undergo any stable crystallization transformation to an appreciable degree, as detectable using conventional ex-situ characterization techniques such as transmission electron microscopy and X-ray diffraction.

Referring still to FIG. 8, the kinetics of amorphous-to-crystalline phase transformation of one embodiment of a memory device comprising a chalcogenide composition and additionally comprising a metallic glass-forming composition is illustrated by a second TTT curve 152. The chalcogenide composition of the chalcogenide material mixture can be the same chalcogenide composition C₀ of FIG. 4 represented by the TTT curve 154. The second TTT curve 152 includes a second nose 152a and a second retention point 152b. At the origin of the TTT diagram 150, the chalcogenide material mixture is fully amorphized by applying a RESET pulse such as the RESET current pulse 82 in FIG. 3. The second nose 152a represents a condition for fastest temperature-time combination, and is characterized by a temperature for maximum transformation rate T_{SET,FS}′ higher than T_{SET,FS} of the first TTT curve 154 and a corresponding time-to-transform t_{SET,FS}′ substantially shorter than t_{SET,FS} of the first TTT curve 154. In one embodiment, where the memory device is optimized to SET at or near a maximum speed, t_{SET,FS}′ and T_{SET,FS}′ may substantially correspond to t_{SET} and T_{SET} of FIG. 3. In other embodiments, where the memory device is optimized to SET at a speed less than a maximum speed, t_{SET,FS}′ may correspond to SET time shorter than t_{SET} of FIG. 3 and T_{SET,FS}′ may correspond to a SET temperature deviating from T_{SET} of FIG. 3. The second retention point 152b represents the time it takes for a fully amorphized chalcogenide material mixture to complete the phase transformation at room temperature T_{RT}.

In one embodiment, T_{SET,FS}′ of a chalcogenide material mixture including both a chalcogenide composition and a metallic glass-forming composition is higher than T_{SET,FS} of a chalcogenide material mixture including the chalcogenide composition without the metallic glass-forming composition by a temperature difference in the range of 1° C. to 100° C. In another embodiment, T_{SET,FS}′ is higher than T_{SET,FS} by a temperature difference in the range of 1° C. to 50° C. In yet another embodiment, T_{SET,FS}′ is higher than T_{SET,FS} by a temperature difference in the range of 1° C. to 20° C.

In one embodiment, t_{SET,FS}′ of a chalcogenide material mixture including both a chalcogenide composition and a metallic glass-forming composition is shorter than t_{SET,FS} of a chalcogenide material mixture including the chalcogenide composition without the metallic glass-forming composition by a time factor difference in the range of 1× to 1000×. In another embodiment, t_{SET,FS}′ is shorter than t_{SET,FS} by a time difference factor in the range of 1× to 100×. In yet another embodiment, t_{SET,FS}′ is shorter than t_{SET,FS} by a time difference in the range of 1× to 10×.

In one embodiment, t_{RET}′ of a chalcogenide material mixture including both a chalcogenide composition and a metallic glass-forming composition is longer than t_{RET} of a chalcogenide material mixture including the chalcogenide composition without the metallic glass-forming composition by a time factor difference in the range of 1× to 1000×. In another embodiment, t_{RET}′ is longer than t_{RET} by a time difference factor in the range of 1× to 100×. In yet another embodiment, t_{RET}′ is longer than t_{RET} by a time difference in the range of 1× to 10×. Correspondingly, an activation energy E_{SET,FS}′ associated with a time-to-transform based on Equation (2) above for a chalcogenide material mixture including both a chalcogenide composition and a metallic glass-forming composition is higher than the activation energy E_{SET,FS} of the chalcogenide material mixture including a chalcogenide composition without the metallic glass-forming composition. In one embodiment, the activation energy E_{SET,FS}′ is between about 0.1 eV and 1.5 eV. In another embodiment, the activation energy E_{SET,FS}′ is between about 2.5 eV and 3.5 eV. In yet another embodiment, the activation energy E_{SET,FS}′ is between about 3.5 eV and 5 eV.

As discussed above, the time difference between the time to transform at the nose and the time to transform at room temperature can be a critical factor for a person skilled in the art in designing the memory devices. Where a fast SET speed and a long retention time is simultaneously desired, a large ratio between t_{RET}′ and t_{SET,FS}′ is desired. In one embodiment, the ratio of t_{RET} to t_{SET,FS}′ is 1×10¹² to 1×10²⁰. In another embodiment, the ratio of t_{RET} to t_{SET,FS}′ is 1×10¹⁴ to 1×10¹⁸. In yet another embodiment, the ratio of t_{RET}′ to t_{SET,FS}′ is 1×10¹⁵ to 1×10¹⁶.

In one embodiment, a memory device such as the memory device 60 of FIGS. 2A and 2B comprising a chalcogenide material mixture in the storage node 38 having a chalcogenide composition and a metallic glass-forming composition disposed between the first and second electrodes 32 and 40 is fabricated through a series of steps including depositing a second electrode layer, depositing the chalcogenide material mixture layer on the second electrode layer, depositing a first electrode layer on the chalcogenide material mixture layer, and etching the first electrode layer, the chalcogenide material mixture layer, and the second electrode layer using a single photo mask.

In another embodiment, a memory device such as the memory device 60 of FIGS. 2A and 2B comprising a first chalcogenide material mixtures having a first chalcogenide composition and a first metallic glass-forming compositions in the storage node 38 and additionally comprising a second chalcogenide material mixture having a second chalcogenide composition and a second metallic glass-forming composition in the selector node 34 is deposited through a series of steps described herein. In this embodiment, the selector node 34 may be disposed between the first and middle electrodes 32 and 36 and the storage node 38 may be disposed between the middle and second electrodes 36 and 40. The memory device of this embodiment is fabricated through a series of steps including depositing a second electrode layer, depositing the first chalcogenide material mixture layer on the second electrode layer, depositing the middle electrode layer on the first chalcogenide material mixture layer, depositing a second chalcogenide material mixture layer on the middle electrode layer, depositing a first electrode layer on the second chalcogenide material mixture layer, and etching the first electrode layer, the second chalcogenide material mixture layer, the middle electrode layer, the first chalcogenide material mixture layer, and the second electrode layer using a single photo mask.

In one embodiment, the metallic glass-forming composition includes a first metal chosen from the group of Sc, Y, a lanthanide element, an actinide element, Ti, Zr, Hf, V, Nb, and Ta. The metallic glass-forming composition further includes a second metal chosen from the group of Cu, Ag, Au, Fe, Co, Ni, Pd, Pt, Co, Rh, Ir, Fe, Ru, Os, Zn, Cd, and Hg. In this embodiment, the first metallic glass-forming element has a first atomic radius and the second glass-forming element has a second atomic radius, and the difference between the first and second atomic radii is at least 12.5% relative to the larger of the first and second radii.

In another embodiment, the metallic glass-forming composition of the second target further comprises a third metal, different from the first and second metals, and chosen from the group of Al, Cu, Ag, Au, Fe, Co, Ni, Pd, Pt, Co, Rh, Ir, Fe, Ru, Os, Zn, Cd, and Hg, Sc, Y, a lanthanide element, an actinide element, Ti, Zr, Hf, V, Nb, and Ta. The third metal has a third atomic radius between the first and second atomic radii. In this embodiment, the third metallic glass-forming element has a third atomic radius, and the difference between the first and third atomic radii is at least 12.5% and the difference between the second and third atomic radii is at least 12.5%.

In one embodiment, the chalcogenide material mixture layer including a chalcogenide composition and a metallic glass-forming composition is fabricated by sputtering a first target comprising a chalcogenide composition and a metallic glass composition. In another embodiment, the chalcogenide material mixture layer including a chalcogenide composition and a metallic glass-forming composition is fabricated by co-sputtering a first target comprising a chalcogenide composition and a second target comprising at least one of the first and second metals. In another embodiment, the chalcogenide material mixture layer including a chalcogenide composition and a metallic glass-forming composition is fabricated by co-sputtering a first target comprising a chalcogenide composition and a second target comprising both of the first and second metals. In another embodiment, the chalcogenide material mixture layer including a chalcogenide composition and a metallic glass-forming composition is fabricated by co-sputtering a first target comprising a chalcogenide composition and a second target comprising at least two of the first, second and third metals. In another embodiment, the chalcogenide material mixture layer including a chalcogenide composition and a metallic glass-forming composition is fabricated by co-sputtering a first target comprising a chalcogenide composition and a second target comprising all three of the first, second, and third metals.

Although this invention has been described in terms of certain embodiments, other embodiments that are apparent to those of ordinary skill in the art, including embodiments that do not provide all of the features and advantages set forth herein, are also within the scope of this invention. Moreover, the various embodiments described above can be combined to provide further embodiments. In addition, certain features shown in the context of one embodiment can be incorporated into other embodiments as well. Accordingly, the scope of the present invention is defined only by reference to the appended claims.

What is claimed is:

1. An electronic device comprising:
a first electrode;
a second electrode; and
a chalcogenide material mixture disposed between the first and second electrodes, the chalcogenide material mixture comprising a chalcogenide composition intermixed with a metallic glass-forming composition.

2. The electronic device of claim 1, wherein the metallic glass-forming composition comprises a first metal element having a first atomic radius and a second metal element having a second atomic radius, wherein a difference between the first and second atomic radii is at least 12.5% relative to the smaller of the first and second radii.

3. The electronic device of claim 2, wherein the first metal element is chosen from the group of Sc, Y, a lanthanide element, an actinide element, Ti, Zr, Hf, V, Nb, and Ta.

4. The electronic device of claim 3, wherein the second metal element is chosen from the group of Cu, Ag, Au, Fe, Co, Ni, Pd, Pt, Co, Rh, Ir, Fe, Ru, Os, Zn, Cd, and Hg.

5. The electronic device of claim 4, wherein the metallic glass-forming composition further comprises a third metal element different from the first and second metal elements and chosen from the group of Al, Cu, Ag, Au, Fe, Co, Ni, Pd, Pt, Co, Rh, Ir, Fe, Ru, Os, Zn, Cd, and Hg, Sc, Y, a lanthanide element, an actinide element, Ti, Zr, Hf, V, Nb, and Ta.

6. The electronic device of claim 2, wherein the metallic glass-forming composition further comprises a third metal element having a third atomic radius, and wherein the difference between the first and third atomic radii is at least 12.5% relative to the larger of the first and third atomic radii and the difference between the second and third atomic radii is at least 12.5% relative to the smaller of the second and third atomic radii.

7. The electronic device of claim 2, wherein the chalcogenide composition corresponds to an equilibrium phase diagram composition having a first solid equilibrium phase corresponding to a first solid equilibrium temperature range and a second solid equilibrium phase corresponding to a second solid equilibrium temperature range lower than the first solid equilibrium temperature range.

8. The electronic device of claim 7, wherein the metallic glass-forming composition comprises between about 1 and 20 atomic percentage of the chalcogenide material mixture.

9. The electronic device of claim 7, wherein the metallic glass-forming composition comprises between about 1 and 10 atomic percentage of the chalcogenide material mixture.

10. The electronic device of claim 7, wherein the chalcogenide material mixture serves as a storage node in a memory cell.

11. The electronic device of claim, 7, wherein the chalcogenide material mixture has a crystallization activation energy greater than a crystallization activation energy corresponding to the crystallization of the first solid equilibrium phase.

12. The electronic device of claim 10, wherein the storage node comprises a plurality of first chalcogenide grains of the first solid equilibrium phase, each of the plurality of first chalcogenide grains being substantially free of the metallic glass-forming composition.

13. The electronic device of claim 12, wherein the storage node further comprises an intergranular boundary region between two adjacent first chalcogenide grains, the intergranular boundary region being substantially free of the chalcogenide composition.

14. The electronic device of claim 12, wherein an average grain size of the first chalcogenide grains does not exceed 20 nm.

15. The electronic device of claim 10, wherein the storage node is configured to receive an electrical pulse, and upon receiving the electrical pulse, raise a peak temperature of the storage node to a temperature in the first solid equilibrium temperature range exceeding the second solid equilibrium temperature range, and wherein the storage node is configured to be substantially free of the second solid equilibrium phase.

16. The electronic device of claim 1, wherein the chalcogenide material mixture serves as a selector node in a memory cell.

17. The electronic device of claim 16, wherein the chalcogenide material mixture has a chalcogenide composition corresponding to an equilibrium phase diagram composition having a first solid equilibrium phase corresponding to a first solid equilibrium temperature range.

18. The electronic device of claim 1, wherein the chalcogenide material mixture does not contain As.

19. The electronic device of claim 17, wherein the selector node is configured to receive an electrical pulse, and upon receiving the electrical pulse, raise a peak temperature of the selector node to a temperature within the first solid equilibrium temperature range, and wherein the selector node is configured to be substantially amorphous.

20. A method of changing a resistance of an electronic device, comprising:
Providing a chalcogenide material mixture between a first electrode and a second electrode, the chalcogenide material mixture comprising a chalcogenide composition intermixed with a metallic glass-forming composition; and
applying an electrical pulse across the first and second electrodes.

21. The method of claim 20, wherein providing the chalcogenide material mixture comprises intermixing the metallic glass-forming composition into the chalcogenide material mixture, the metallic glass-forming composition comprising a first metal element having a first atomic radius and a second metal element having a second atomic radius, wherein a difference between the first and second atomic radii is at least 12.5% relative to the smaller of the first and second radii.

22. The method of claim 21, wherein providing the chalcogenide material mixture comprises intermixing the chalcogenide composition into the chalcogenide material mixture, the chalcogenide material mixture corresponding to an equilibrium phase diagram composition having a first solid equilibrium phase corresponding to a first solid equilibrium temperature range and a second solid equilibrium phase corresponding to a second solid equilibrium temperature range lower than the first solid equilibrium temperature range.

23. The method of claim 22, wherein providing the chalcogenide mixture comprises providing the chalcogenide material mixture in a storage node of a memory cell, and wherein applying the electrical pulse comprises providing sufficient energy to raise the temperature of the selector node within the first solid equilibrium temperature range.

24. The method of claim 23, wherein applying the electrical pulse comprises lowering a resistance of the storage node from an initial resistance to a final resistance lower than the initial resistance by at least a factor of 10, wherein the initial resistance of the storage node is measured prior to the application of the electrical pulse, the initial resistance corresponding to the chalcogenide material mixture containing an amorphous region, and wherein the final resistance of the storage node is measured after the application of the electrical pulse, the final resistance corresponding to the chalcogenide material mixture comprising a plurality of first chalcogenide grains of the first solid equilibrium phase.

25. The method of claim 21, wherein providing the chalcogenide mixture comprises providing the chalcogenide material mixture having a chalcogenide composition corresponding to an equilibrium phase diagram composition having a solid equilibrium phase corresponding to a solid equilibrium temperature range.

26. The method of claim 25, wherein providing the chalcogenide mixture comprises providing the chalcogenide material mixture in a selector node in a memory cell, and wherein applying the electrical pulse comprises providing sufficient energy to raise the temperature of the storage node within the solid equilibrium temperature range.

27. The method of claim 26, wherein applying the electrical pulse comprises lowering a resistance of the selector node during a duration of the electrical pulse, wherein the resistance of the selector node during the duration of the electrical pulse is lower than an initial resistance of the selector node and a final resistance of the selector node by a factor greater than 100, wherein the initial resistance is measured prior to the application of the electrical pulse and the final resistance measured after the application of the electrical pulse, the initial resistance and the final resistance corresponding to the chalcogenide material mixture in a substantially amorphous phase.

28. A method of fabricating an electronic device comprising:
forming a chalcogenide material mixture comprising a chalcogenide composition and a metallic glass-forming composition; and
forming electrodes on opposite sides of the chalcogenide material mixture.

29. The method of claim 28, wherein forming the chalcogenide material mixture comprises intermixing into the chalcogenide material mixture the metallic glass-forming composition, wherein the metallic glass-forming composition comprises a first metal element having a first atomic radius and a second metal element having a second atomic radius, wherein a difference between the first and second atomic radii is at least 12.5% relative to the smaller of the first and second radii.

30. The method of claim 29, wherein forming the chalcogenide material mixture comprises intermixing into the chalcogenide material mixture the first metal element chosen from the group of Sc, Y, a lanthanide element, an actinide element, Ti, Zr, Hf, V, Nb, and Ta.

31. The method of claim 30, wherein forming the chalcogenide material mixture comprises intermixing into the chalcogenide material mixture the second metal element chosen from the group of Cu, Ag, Au, Fe, Co, Ni, Pd, Pt, Co, Rh, Ir, Fe, Ru, Os, Zn, Cd, and Hg.

32. The method of claim 29, wherein forming the chalcogenide material mixture comprises intermixing into the chalcogenide material mixture the metallic glass-forming composition further comprising a third metal element having a third atomic radius, and wherein the difference between the first and third atomic radii is at least 12.5% relative to the smaller of the first and third atomic radii and the difference between the second and third atomic radii is at least 12.5% relative to the smaller of the second and third atomic radii.

33. The method of claim 31, wherein forming the chalcogenide material mixture comprises intermixing into the chalcogenide material mixture the metallic glass-forming composition comprising the third metal element different from the first and second metal elements, and chosen from the group of Al, Cu, Ag, Au, Fe, Co, Ni, Pd, Pt, Co, Rh, Ir, Fe, Ru, Os, Zn, Cd, and Hg, Sc, Y, a lanthanide element, an actinide element, Ti, Zr, Hf, V, Nb, and Ta.

34. The method of claim 29, wherein forming the chalcogenide material mixture comprises sputtering a first target comprising the chalcogenide composition and the metallic glass composition.

35. The method of claim 29, wherein forming the chalcogenide material mixture comprises co-sputtering a first target comprising the chalcogenide composition and a second target comprising at least one of the first and second metal elements.

36. The method of claim 29, wherein forming the chalcogenide material mixture comprises co-sputtering a first target comprising the chalcogenide composition and a second target comprising both of the first and second metal elements.

37. The method of claim 32, wherein forming the chalcogenide material mixture comprises co-sputtering a first target comprising the chalcogenide composition and a second target comprising at least two of the first, second and third metal elements.
The method of claim 32, wherein forming the chalcogenide material mixture comprises co-sputtering a first target comprising the chalcogenide composition and a second target comprising all three of the first, second, and third metal elements.

38. The method of claim 33, wherein forming the chalcogenide material mixture includes choosing the chalcogenide material mixture to include between about 1% and 20% of the metallic glass-forming composition.

39. The method of claim 38, wherein forming the chalcogenide material mixture includes choosing the metallic glass-forming composition to include between about 1% and 10% of the third metal element.
